(19) United States
(12) Patent Application Publication
(10) Pub. No.: US 2013/0313714 A1
(43) Pub. Date: Nov. 28, 2013

(54) SEMICONDUCTOR DEVICE HAVING ENHANCED SIGNAL INTEGRITY

(71) Applicant: SAMSUNG ELECTRONICS CO., LTD., Suwon-Si (KR)

(72) Inventors: Jong Hyun SEOK, Seoul (KR); Do Hyung KIM, Hwaseong-si (KR); Kwang Seop KIM, Yongin-si (KR)

(73) Assignee: SAMSUNG ELECTRONICS CO., LTD., Suwon-Si (KR)

(21) Appl. No.: 13/837,891

(22) Filed: Mar. 15, 2013

Related U.S. Application Data
(60) Provisional application No. 61/649,999, filed on May 22, 2012.

(30) Foreign Application Priority Data
Jul. 17, 2012 (KR) 10-2012-0077848

(51) Int. Cl. H01L 23/50

(52) U.S. Cl. CPC H01L 23/50
USPC 257/773

(57) ABSTRACT

A semiconductor includes a first signal line commonly connected to a plurality of semiconductor devices and a second signal line commonly connected to one or more of the plurality of semiconductor devices. The first signal line has a first impedance per unit length, the second signal line has a second impedance per unit length, the second impedance per unit length is greater than the first impedance per unit length, and the first signal line has a longer routing length than the first signal line. Widths of the signal lines may be set to reduce a difference in the impedances.

### CROSS-REFERENCE TO RELATED APPLICATIONS

This application claims benefit of U.S. provisional patent application No. 61/649,999 filed on May 22, 2012 and the priority under 35 U.S.C. §119 (a) from Korean Patent Application No. 10-2012-0077848, filed on Jul. 17, 2012, the disclosures of these applications are incorporated by reference in their entirety.

### BACKGROUND

1. Field

The inventive concept relates to semiconductor devices including but not limited to ones having a memory module with a plurality of memory chips.

2. Description of Related Art

In a memory module included in a semiconductor device, a plurality of memory chips is installed. The memory chips exchange control signals and data signals with an external device via an interface. Thus, signal integrity is one of important factors that determine features of the memory module.

### SUMMARY

According to an example embodiment of the inventive concept, there is provided a semiconductor device including a first signal line commonly connected to N first semiconductor elements, wherein N is a natural number that is greater than ‘2’; and a second signal line commonly connected to M second semiconductor elements, wherein M is a natural number that is greater than N, wherein the first signal line has a higher impedance per unit length than the second signal line, and has a longer routing length compared to the second signal line by changing a wire pattern between both ends of each of the first and the second signal lines.

Unit loads on the first semiconductor elements and unit loads on the second semiconductor elements may be substantially the same, and a load connected to the second signal line may be higher than a load connected to the first signal line.

The first semiconductor elements, the second semiconductor elements, the first signal line, and the second signal line may be integrated on the same substrate.

The impedance of the first signal line per unit length may be 1.2 or more times greater than the impedance of the second signal line per unit length. A width of the second signal line may be 1.5 or more times wider than a width of the first signal line.

The semiconductor device may further include a third signal line commonly connected to P third semiconductor elements, wherein P is a natural number greater than M.

The second semiconductor elements may include some of the first semiconductor elements, the third semiconductor elements may include some of the first and second semiconductor elements, and the third signal line may have a lower impedance per unit length than the second signal line.

According to another example embodiment of the inventive concept, there is provided a semiconductor device including a first signal line commonly connected to a plurality of semiconductor elements; and a second signal line commonly connected to some of the plurality of semiconductor elements, wherein the second signal line has a higher impedance per unit length than the first signal line, and has a longer routing length compared to the first signal line by changing a wire pattern between both ends of each of the first and the second signal lines.

According to another example embodiment of the inventive concept, there is provided a semiconductor device including a first signal line commonly connected to N first semiconductor elements, wherein N is a natural number that is greater than 2; a second signal line commonly connected to N second semiconductor elements; and a third signal line commonly connected to the first and second semiconductor elements, wherein the first and second signal lines have a higher impedance per unit length than the third signal line.

According to another embodiment, a semiconductor apparatus includes a first signal line commonly connected to N first semiconductor devices, wherein N is a natural number that is greater than 2, and a second signal line commonly connected to M second semiconductor devices, wherein M is a natural number that is greater than N. The first signal line has a first impedance per unit length, the second signal line has a second impedance per unit length less than the first impedance per unit length, the first signal line extends between a first location and a second location in a first pattern, the second signal line extends between the first location and the second location in a second pattern different from the first pattern, and the first signal line has a longer routing length than the second signal line between the first and second locations based on a difference between the first pattern and the second pattern.

The first signal line may have a first width, the second signal line may have a second width, and a difference between the first impedance per unit length and the second impedance per unit length is based on a difference between the first width and the second width.

The apparatus may further include a substrate, wherein the first semiconductor devices are connected to a first surface of a first substrate and wherein at least a portion of the second semiconductor devices are connected to a second surface of the first substrate.

The apparatus may further include a substrate, wherein the first and second semiconductor devices are stacked and connected to a first surface of a substrate.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 illustrates a semiconductor device according to an example embodiment of the inventive concept.

FIG. 2 is a diagram schematically illustrating a memory module according to an example embodiment of the inventive concept.

FIG. 3 is a diagram schematically illustrating a memory module according to another example embodiment of the inventive concept.

FIG. 4A is a diagram illustrating a connection among memory devices included in a memory module and a memory controller/host according to an example embodiment of the inventive concept.

FIG. 4B is a diagram illustrating a connection among memory devices included in a memory module and a memory controller/host according to another example embodiment of the inventive concept.

FIG. 5 is a diagram schematically illustrating net structure routing performed on a command/address signal in a memory module according to an example embodiment of the inventive concept.

FIG. 6 is a diagram schematically illustrating net structure routing performed on a control signal in a memory module according to an example embodiment of the inventive concept.

FIG. 7 is a signal timing diagram illustrating a time delay occurring between transmission of individual rank signals and transmission of a common rank signal according to a comparative example of the inventive concept.

FIG. 8 is a diagram illustrating an example of signal routing performed on a module substrate of a dual in-line memory module (DIMM) for use in a dynamic random access memory (DRAM).

FIG. 9 is a diagram illustrating wires of a memory module according to a comparative example of the inventive concept.

FIG. 10 is a diagram illustrating wires of a memory module according to an example embodiment of the inventive concept.

FIG. 11 is a diagram illustrating wires of a memory module according to another example embodiment of the inventive concept.

FIG. 12 is a block diagram illustrating one type of interface of a memory module connected to a memory controller.

FIG. 13 is a block diagram of an electronic system including a semiconductor memory device according to an example embodiment of the inventive concept.

FIG. 14 is a block diagram of a single-chip microcomputer including a semiconductor memory device according to an example embodiment of the inventive concept.

### DETAILED DESCRIPTION OF THE EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

In the drawings, it is understood that the thicknesses of layers and regions may be exaggerated for clarity. It will also be understood that when a layer is referred to as being “on” another layer or substrate, it can be directly on the other layer or substrate or intervening layers may also be present. Like reference numerals in the drawings denote like elements, and thus their description will not be repeated. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

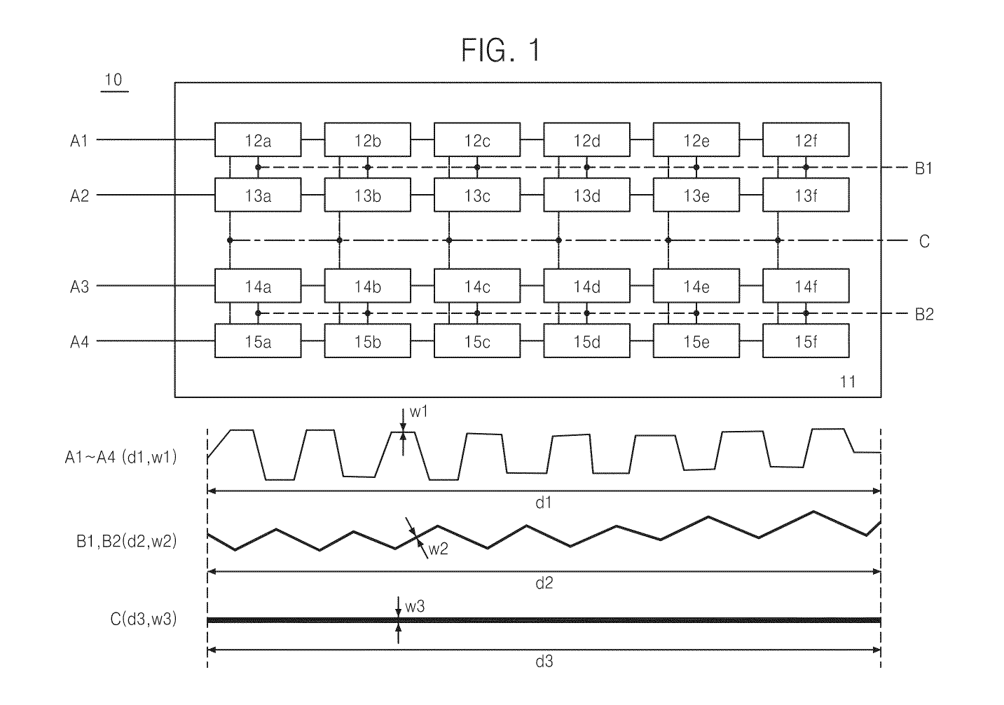

FIG. 1 shows a semiconductor device 10 according to an example embodiment of the inventive concept. Referring to FIG. 1, the semiconductor device 10 includes a substrate 11, a plurality of semiconductor chips 12a to 12f commonly connected to a first signal line A1, a plurality of semiconductor chips 13a to 13f commonly connected to a second signal line A2, a plurality of semiconductor chips 14a to 14f commonly connected to a third signal line A3, and a plurality of semiconductor chips 15a to 15f commonly connected to a fourth signal line A4.

A fifth signal line B1 is commonly connected to the plurality of semiconductor chips 12a to 12f commonly connected to the first signal line A1 and the plurality of semiconductor chips 13a to 13f commonly connected to the second signal line A2. signal line B2 is commonly connected to the plurality of semiconductor chips 14a to 14f commonly connected to the third signal line A3 and the plurality of semiconductor chips 15a to 15f commonly connected to the fourth signal line A4.

A seventh signal line C is commonly connected to the plurality of semiconductor chips 12a to 12f commonly connected to the first signal line A1, the plurality of semiconductor chips 13a to 13f commonly connected to the second signal line A2, the plurality of semiconductor chips 14a to 14f commonly connected to the third signal line A3, and the plurality of semiconductor chips 15a to 15f commonly connected to the fourth signal line A4.

Since each of the first to fourth signal lines A1 to A4 is connected to six semiconductor chips, six loads are considered as being connected to each of the first to fourth signal lines A1 to A4.

Since each of the fifth and sixth signal lines B1 and B2 is connected to twelve semiconductor chips, the number of loads connected to each of the fifth and sixth signal lines B1 and B2 is double the number of loads connected to each of the first to fourth signal lines A1 to A4.

Since the seventh signal line C is connected to twenty-four semiconductor chips, the number of loads connected to the seventh signal line C is four times the number of loads connected to each of the first to fourth signal lines A1 to A4 and is two times the number of loads connected to each of the fifth and sixth signal lines B1 and B2.

In accordance with an example embodiment, each of the first to seventh signal lines A1 to A4,B1,B2, and C is configured to select at least one of the semiconductor chips 12a to 15f so as to drive the semiconductor device 10, to transmit a control signal, and to allow data to be written to the semiconductor device 10 or to be read from the semiconductor device 10. Thus, timings of the first to seventh signal lines A1 to A4,B1,B2, and C should coincide.

In accordance with an example embodiment, each of the first to seventh signal lines A1 to A4, B1, B2, and C may carry at least one control signal such as a command signal, an address signal, a select signal, etc. Also, each of the first to seventh signal lines A1 to A4, B1, B2, and C may carry a clock signal and/or a data signal.

Different loads on the first to seventh signal lines A1 to A4, B1, B2, and C cause different impedances among the first to seventh signal lines A1 to A4, B1, B2, and C as described above. Such different impedances may cause a reduction in a timing margin, thereby degrading signal integrity.

To compensate for the different impedances among the first to seventh signal lines A1 to A4, B1, B2, and C, the widths and/or lengths of these signal lines may be adjusted. In accordance with one embodiment, the adjustments may be based on the principle that an increase in the width of a signal line results a reduction in an impedance thereof and an increase in the length of the signal line results in an increase the impedance thereof.

For example, each of the first to fourth signal lines A1 to A4 may have a narrowest width ‘w1,’ each of the fifth and sixth signal lines B1 and B2 may have a width ‘w2’ that is wider than the width ‘w1’ of each of the first to fourth signal lines A1 to A4, and the seventh signal line C may have a width ‘w3’ that is wider than the width ‘w2’ of each of the fifth and sixth signal lines B1 and B2.

In this case, an impedance of a unit length of each of the first to fourth signal lines A1 to A4 is highest, and an impedance of a unit length of each of the fifth and sixth signal lines B1 and B2 is higher than an impedance of a unit length of the seventh signal line C and is lower than an impedance of a unit length of each of the first to fourth signal lines A1 to A4.

These widths may be provided without changing lengths of the signal lines. In accordance with an example embodiment, all the signal lines may have substantially a same length but different widths as noted above. In other example embodiments, the lengths of one or more of these lines (or sets of lines) may be different.

In another example embodiment, in addition to having different widths as noted above, the lengths of the signal lines may be different. According to one example, the first to seventh signal lines A1 to A4, B1, B2, and C may be set such that scalar values d1 to d3 thereof are substantially the same but vectors thereof are different. To this end, patterns of the first to fourth signal lines A1 to A4, the fifth and sixth signal lines B1 and B2, and the seventh signal line C may be changed as illustrated in FIG. 1.

As shown in FIG. 1, the scalar values d1 to d3 may be understood to be linear distances (or shortest distances) between both ends of the respective first to seventh signal lines A1 to A4, B1, B2, and C. Although the scalar values d1 to d3 are substantially the same, actual lengths of the respective first to seventh signal lines A1 to A4, B1, B2, and C (the lengths between both ends thereof when these signal lines are stretched in a straight line) may be different by changing a wire pattern between both ends of each of the first to seventh signal lines A1 to A4, B1, B2, and C. Accordingly, the vectors of these signal lines are different.

The impedances among the first to seventh signal line A1 to A4,B1,B2, and C to which different loads are connected may be set to be substantially the same by changing the lengths and widths thereof. A timing margin between signals may be increased through such impedance adjustment, thereby enhancing signal integrity.

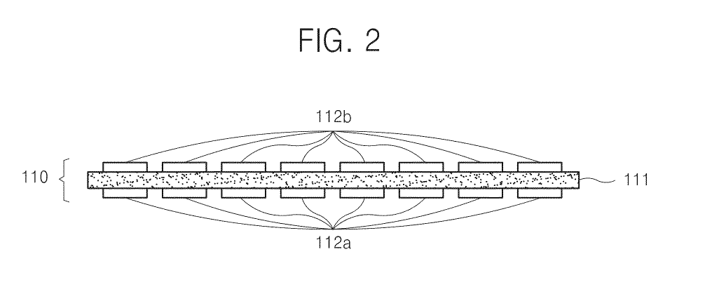

FIG. 2 is a diagram schematically illustrating a memory module 110 according to an example embodiment of the inventive concept. Referring to FIG. 2, the memory module 110 includes a module substrate 111, a plurality of memory devices 112a mounted on one surface (e.g., front surface) of the module substrate 111, and a plurality of memory devices 112b mounted on another surface (e.g., back surface) of the module substrate 111. The plurality of memory devices 112a mounted on one surface (e.g., front surface) of the module substrate 111 may form a first rank together and the plurality of memory devices 112b mounted on another surface (e.g., back surface) of the module substrate 111 may form a second rank together.

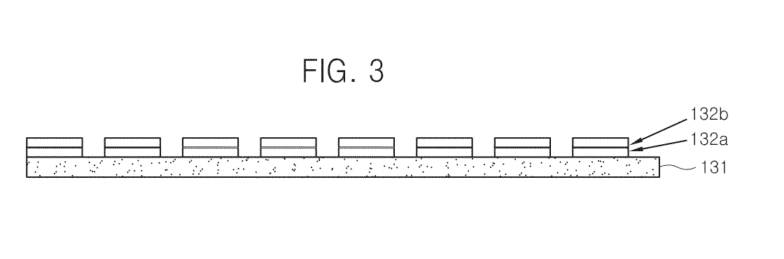

FIG. 3 is a diagram schematically illustrating a memory module according to another example embodiment of the inventive concept. The memory module of FIG. 3 includes a plurality of memory devices 132a and a plurality of memory devices 132b stacked in a two-storied structure on one surface of a module substrate 131. The plurality of memory devices 132a mounted on a first layer of the module substrate 131 may form a first rank together and the plurality of module substrate 131 mounted on a second layer of the module substrate 131 may form a second rank together.

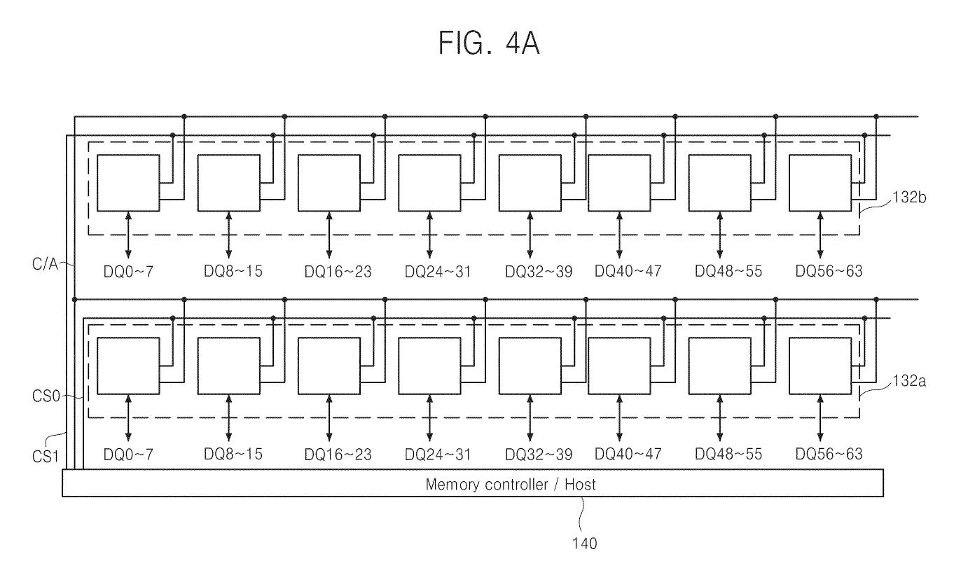

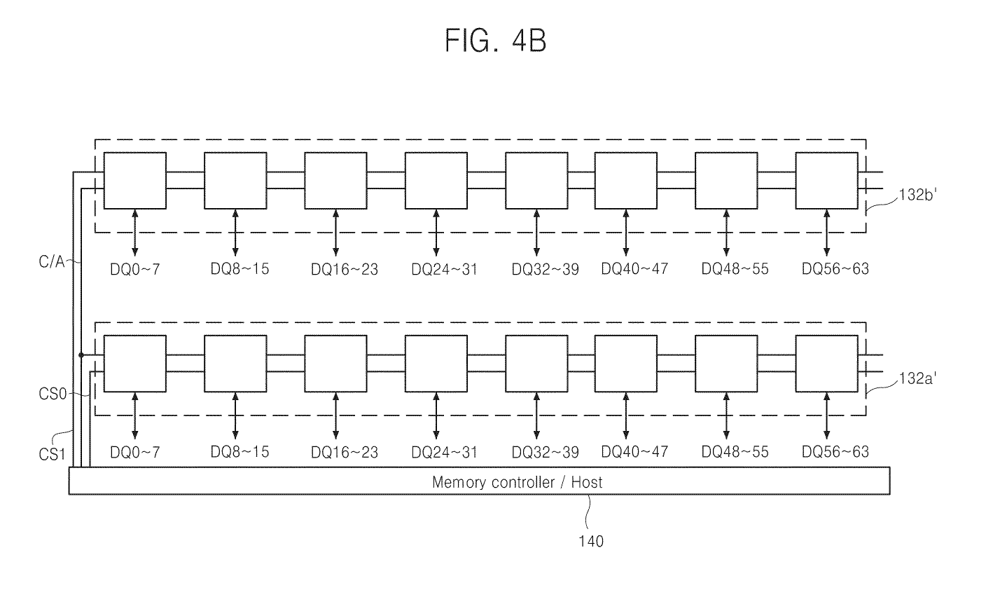

FIG. 4A is a diagram illustrating a connection among memory devices 132a and 132b in a memory module and a memory controller/host 140 according to an example embodiment of the inventive concept. The memory controller/host 140 may be located outside the memory module. Here, reference numeral 140 may denote a memory controller or a host.

The memory controller/host 140 and the memory devices 132a and 132b may be connected according to a multi-drop scheme but the inventive concept is not limited thereto. For example, eight (or another number of) memory devices may form one rank together. A group of memory devices that are simultaneously controlled by the memory controller/host 140 may be referred to as a rank. In other words, a rank may be a unit in which an operation is performed in the memory module.

The operation may be, for example, a data read operation or a data write operation. For example, when data is input into and output from the memory controller/host 140 in units of 64 bits (x64) and data is input into and output from each of the memory devices 132a and 132b in units of 8 bits (x8), eight memory devices may form one rank together.

Referring to FIGS. 4A and 4B, in one example embodiment, a control signal CS0 supplied to the memory devices 132a belonging to a first rank and a control signal CS1 supplied to the memory devices 132b belonging to a second rank are separated from each other. A command/address signal C/A may be commonly input to the first rank and the second rank. The control signals CS0 and CS1 that are separately input in units of ranks may include a chip selection signal S, a clock signal, a clock enable signal CKE, and/or an on-die termination signal ODT.

If it is assumed that a chip selection signal input to the first rank is ‘/S0’ and a chip selection signal input to the second rank is ‘/S1,’ then the memory device 132a belonging to the first rank is selected when the memory controller/host 140 enables the chip selection signal ‘/S0’ to logic low and the memory devices 132b belonging to the second rank is selected when the memory controller/host 140 enables the chip selection signal ‘/S1’ to logic low. Since data is output from each of the memory devices 132a and 132b in units of 8 bits, 64-bit data is simultaneously input to or output from the memory controller/host 140. This may be referred to as an x64 operation.

FIG. 4B is a diagram illustrating a connection among memory devices 132a′ and 132b′ in a memory module and a memory controller/host 140 according to another example embodiment of the inventive concept. The memory devices 132a′ and 132b′ may belong to the same rank and may be connected according to a chain manner.

According to another example embodiment of the inventive concept, a plurality of memory devices included in a memory module may be connected in a fly-by manner.

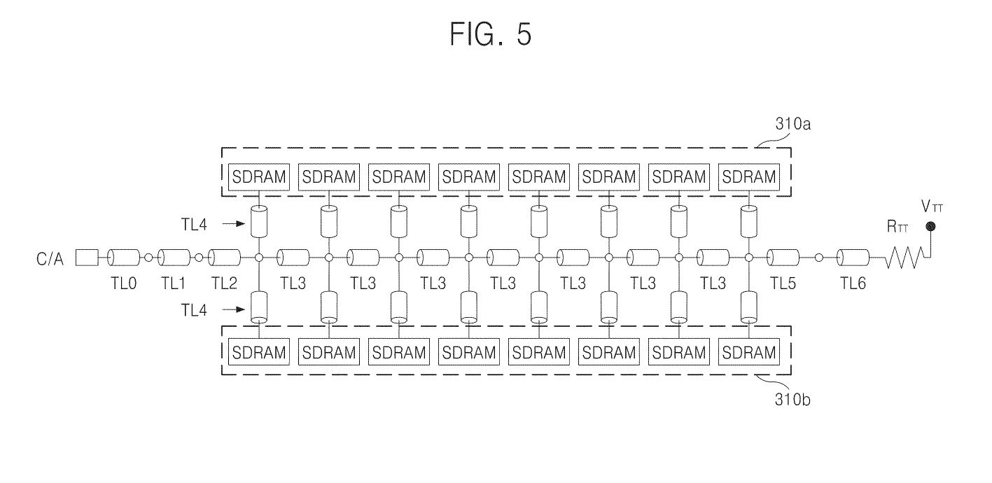

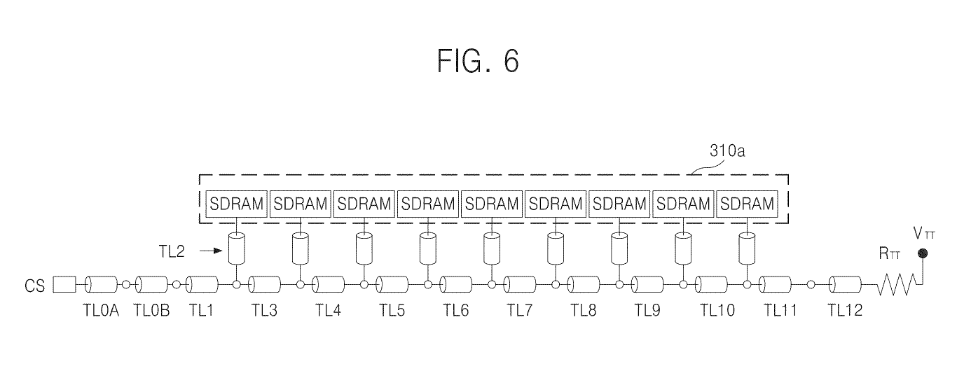

FIG. 5 is a diagram schematically illustrating net structure routing performed on a command/address signal C/A in a memory module according to an example embodiment of the inventive concept. FIG. 6 is a diagram schematically illustrating net structure routing performed on a control signal CS in a memory module according to an example embodiment of the inventive concept.

Referring to FIG. 5, the memory module includes a plurality of ranks 310a and 310b. The command/address signal C/A is commonly input to the plurality of ranks 310a and 310b. A signal that is being commonly input to the plurality of ranks is referred to as a common rank signal. The common rank signal may include an address signal and a command signal. The command signal may include, for example, a row access strobe signal RAS, a column access strobe signal CAS, and a write enable signal WE, but the inventive concept is not limited thereto.

Referring to FIG. 6, the control signal CS is individually input to a target rank among a plurality of ranks. FIG. 6 illustrates the control signal CS corresponding to a first rank 310a. A control signal that is individually input to each of ranks is referred to as an individual rank signal. The individual rank signal may include the chip selection signal S, the clock signal CK, the clock enable signal CKE, and the on-die termination signal ODT described above, but the inventive concept is not limited thereto.

In FIGS. 5 and 6, ‘TL0’ to ‘TL12’ denote wire lengths. A wire length may be determined according to a standard, e.g., the JEDEC standard. According to the JEDEC standard, ‘TL0’ to ‘TL12’ are referred to as trace lengths.

The individual rank signal is input to only a corresponding rank and a load applied to the individual rank signal is lower than that applied to the common rank signal. If it is assumed that a memory module includes only two ranks, a higher load is applied to the common rank signal than that applied to the individual rank signal. For example, since a load applied to the common rank signal doubles that applied to the individual rank signal, the common rank signal experiences an impedance that is 1.2 to 2.4 times greater than an impedance experienced by the individual rank signal.

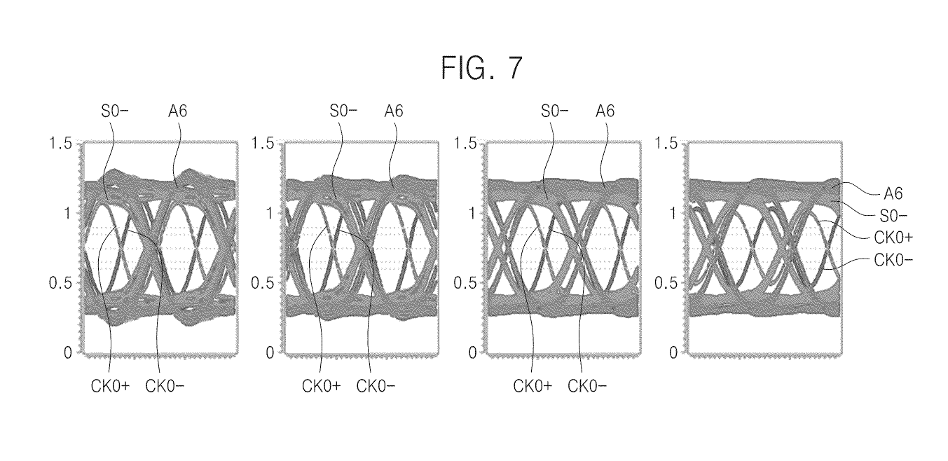

As described above, when wire lengths of the individual rank signal and the common rank signal are the same although different loads are applied thereto, signal transfer times are different due to different impedances thereof. Thus, as illustrated in FIG. 7, a time delay occurs between transmission of the individual rank signal and transmission of the common rank signal, thereby reducing a timing margin.

More specifically, FIG. 7 is a signal timing diagram illustrating a time delay occurring between transmission of individual rank signals and transmission of a common rank signal according to a comparative example of the inventive concept. In FIG. 7, ‘A6’ denotes a common rank signal, and ‘S0’, ‘CK0+’, and ‘CK0−’ denote individual rank signals.

To reduce the time delay occurring between transmission of the individual rank signals and transmission of the common rank signal, routing (wire) lengths and widths of the individual rank signals may be adjusted. For example, the routing (wire) lengths of the individual rank signals may be increased.

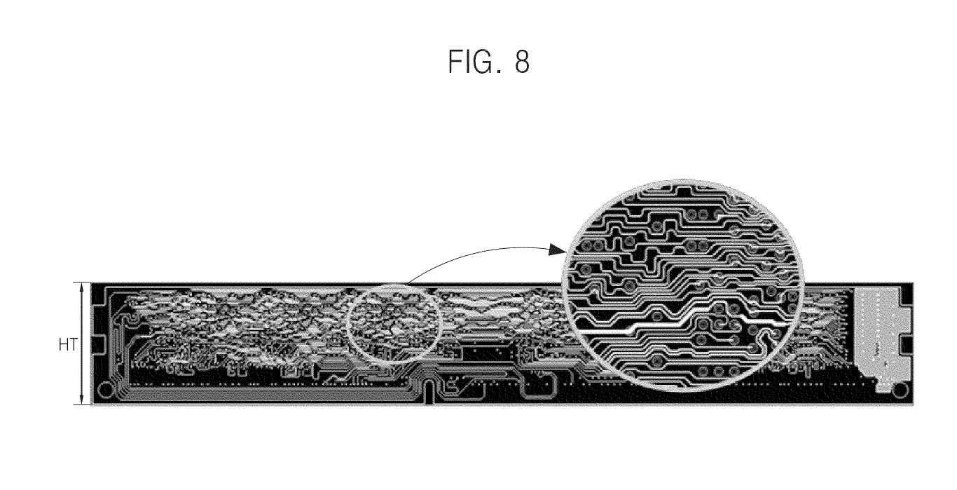

FIG. 8 is a diagram illustrating signal routing performed on a module substrate of a dual in-line memory module (DIMM) for use in a dynamic random access memory (DRAM). Referring to FIG. 8, in the case of a certain DIMM, the height HT thereof is low and a routing space is thus insufficient. Thus, a number of layers should be increased to increase a routing length or a wire length, thereby increasing manufacturing costs.

Although not shown, an un-buffered dual in-line memory module (UDIMM) and a small outline dual in-line memory module (SODIMM) each include a wide signal line section. This section may be referred to as an unloaded section. Due to such an unloaded section, routing space may be insufficient. Thus, a number of layers should be increased to increase a routing length or a wire length, thereby increasing manufacturing costs.

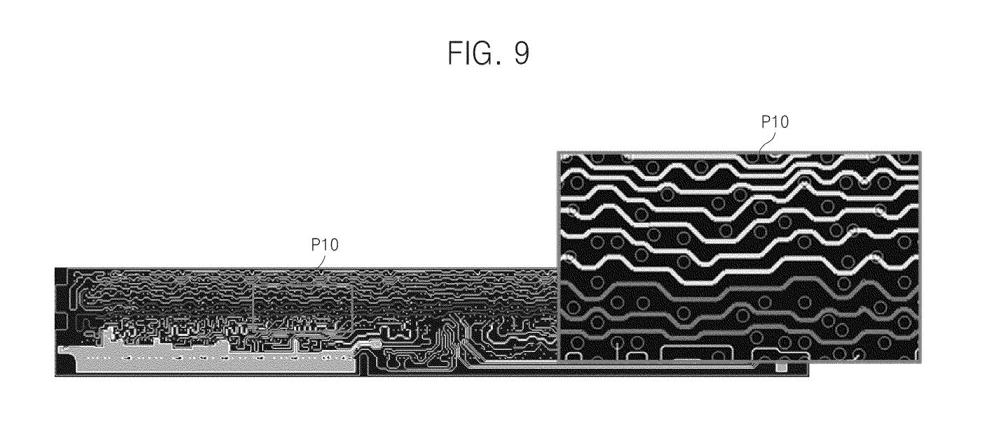

FIG. 9 is a diagram illustrating wires of a memory module according to a comparative example of the inventive concept. Referring to FIG. 9, only signal lines having the same thickness, i.e., wider signal lines, are arranged in a specific wire section P10. Thus, an additional wiring space may be insufficient.

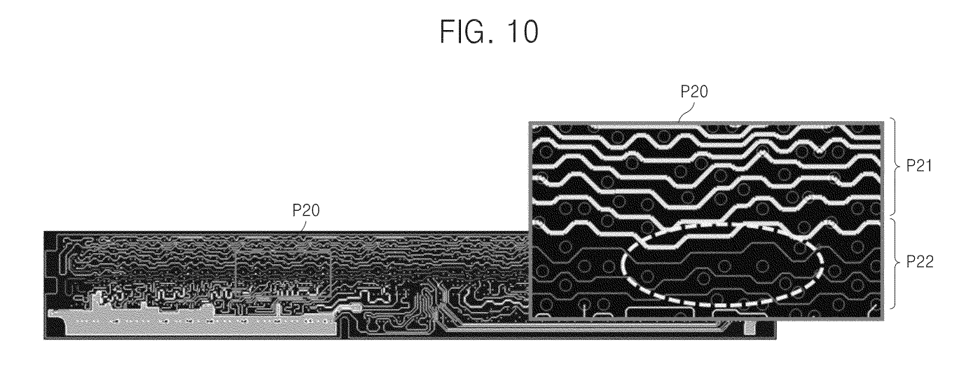

FIG. 10 is a diagram illustrating wires of a memory module according to an example embodiment of the inventive concept. Referring to FIG. 10, signal lines of two types are installed together in a specific wire section P20 of the memory module. Signal lines of a first type P21 have a pattern having relatively wide signal lines, and signal lines of a second type P22 have a pattern having relatively narrow signal lines. For example, in the specific wire section P20, the signal lines of the first type P21 may be installed as wires for a common rank signal and the signal lines of the second type P22 may be installed as wires for individual rank signals.

Thus, different impedances between the common rank signal and the individual rank signals caused by different loads applied thereto may be adjusted to be substantially the same by changing wire widths and lengths (vectors). For example, wire (routing) widths may be adjusted such that the individual rank signals have impedance that is 1.2 to 2.4 times greater than that of the common rank signal.

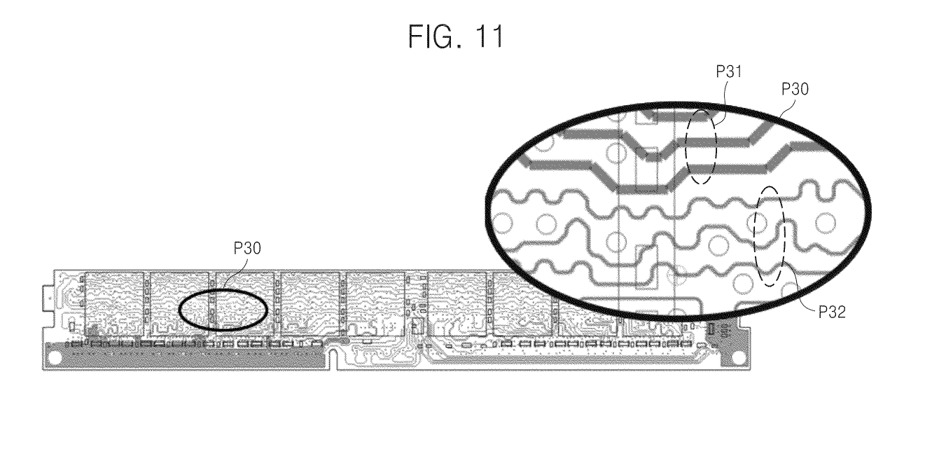

FIG. 11 is a diagram illustrating wires of a memory module according to another example embodiment of the inventive concept. Referring to FIG. 11, in a specific wire section P30 of the memory module, signal lines of two types are installed, similar to the example embodiment of FIG. 10. Signal lines of a first type P31 have a relatively wide width and signal lines of a second type P32 have a relatively narrow width. For example, in the specific wire section P30, the signal lines of the first type P31 may be installed as wires for a common rank signal, and signals of the second type P32 may be installed as wires for individual rank signals.

A first type (unloaded) signal line and a second type (loaded) signal line may have characteristics shown in Table 1, but the inventive concept is not limited thereto.

TABLE 1

| | Width | Spacing | Recommend (3W) |
|---|---|---|---|
| Unloaded(First Type) | 200 μm | 200 μm | 600 μm |
| Loaded(Second Type) | 100 μm | 100 μm | 300 μm |

As shown in Table 1, the second type signal line may have a width and spacing that are half those of the first type signal line, but the inventive concept is not limited thereto. Also, the first type signal line may have an impedance of about 40Ω and the second type signal line may have an impedance of about 60Ω, but the inventive concept is not limited thereto.

Different widths of the first type signal line and the second type signal line may not be caused by different process conditions but may be intentionally designed. For example, the width of the first type signal line may be 1.5 or more times that of the second type signal line.

As described above, signal lines having different widths are installed as wires for a common rank signal and individual rank signals, thereby securing an additional wiring space. The additional wiring space may be used to increase the routing (or wire) lengths of individual rank signals described above.

For example, in the memory module of FIG. 5 or 6, both first and second signal lines are installed in a section TL1 to secure an additional wiring space, and the additional wiring space may be used to increase routing (or wire) lengths of individual rank signals in at least one among sections TL3, TL4, and TL7. The section TL1 may be a wire section connected to a first memory device of the memory module. The section TL3, TL4, or TL7 may be a wire section between one memory device and another memory device.

Although the previous example embodiments of the inventive concept have been described above with respect to a UDIMM memory module, other example embodiments of the inventive concept are not limited thereto and may be applied to other types of memory modules such as buffered DIMM and SODIMM. Also, the number of ranks is not limited to two. Furthermore, the number of layers of a memory module substrate may be two or more.

In the memory module of FIG. 5 or 6, the section TL1 may be installed in a first layer, and the section TL3, TL4, or TL7 may be installed in a second layer. In this case, both the first type signal and the second type signal line may installed in the first layer to secure an additional wiring space, and wires for individual rank signals in the section TL3, TL4, or TL7 may be installed in the additional wiring space in the first layer to increase routing (or wire) lengths of the individual rank signals.

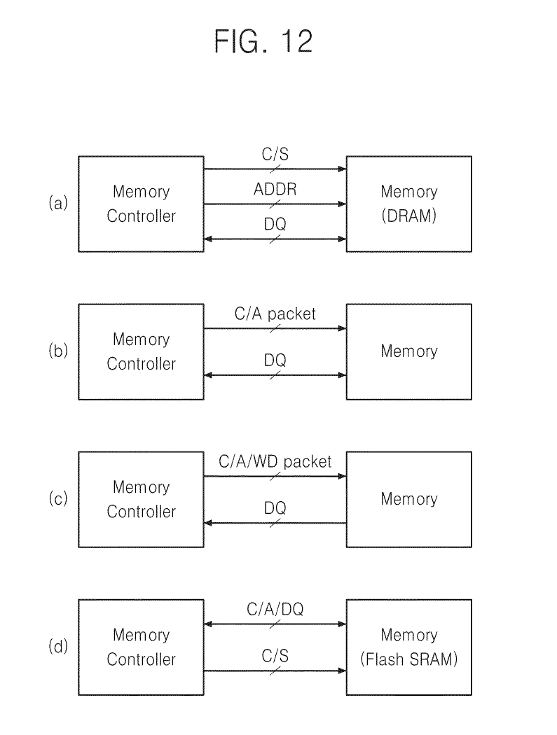

FIG. 12 is a block diagram illustrating an interface of a memory module connected to a memory controller. FIG. 12 illustrates various examples of memory bus protocols between a memory module in which unloaded type wires and loaded type wires as described above are arranged in consideration of loads on signal lines, and a controller.

Specifically, FIG. 12(a) illustrates a bus protocol between a memory controller and a memory module, e.g., a DRAM module. A control signal C/S, e.g., signals /CS, CKE, /RAS, /CAS, and /WE, and an address signal ADDR are provided to the memory module from the memory controller. Data DQ is bi-directionally transmitted between the memory module and the memory controller. The loaded type wires and unloaded type wires may be assigned according to load on these signal lines and connected states thereof.

Referring to FIG. 12(b), packetized control signals and address signals C/A packet are provided to a memory from a memory controller, and data DQ is bi-directionally transmitted between the memory and the memory controller.

Referring to FIG. 12(c), packetized control signals and address signals and write signals C/A/WD Packet are provided to a memory from a memory controller, and output data DQ is uni-directionally transmitted from the memory to the memory controller.

Referring to FIG. 12(d), a control signal C/S is provided from a memory controller to a memory, e.g., flash static random access memory (SRAM), and commands, addresses, and data C/A/DQ is bi-directionally transmitted between the memory and the memory controller.

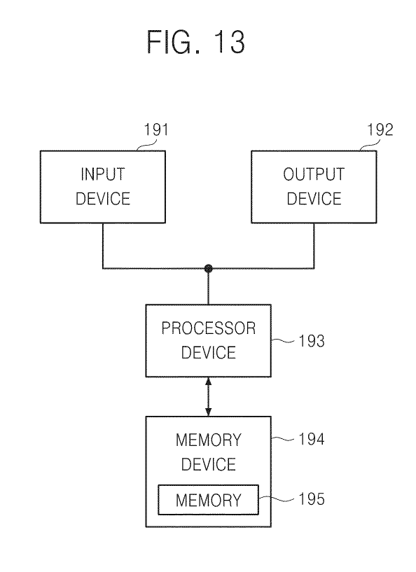

FIG. 13 is a block diagram of an electronic system including a semiconductor memory device according to an example embodiment of the inventive concept. Referring to FIG. 13, the electronic system includes an input device 191, an output device 192, a memory device 194, and a processor device 193.

The memory device 194 includes an interface chip (not shown) and/or a memory controller, and a memory module 195 having a structure illustrated in any one of FIGS. 1 to 12. The processor device 193 is connected to each of the input device 191, the output device 192, and the memory device 194 via a corresponding interface so as to control overall operations of the electronic system.

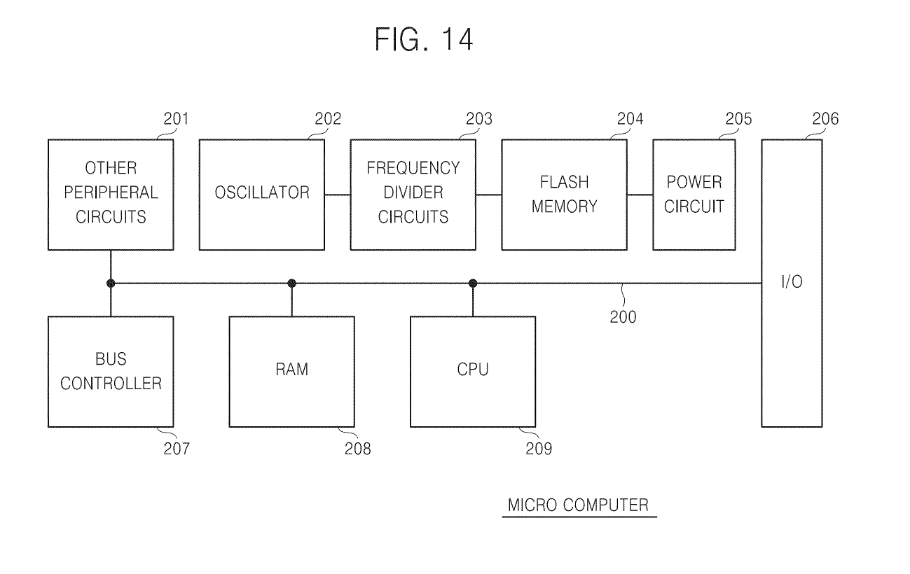

FIG. 14 is a block diagram of a single-chip microcomputer including a semiconductor memory device according to an example embodiment of the inventive concept. Referring to FIG. 14, the microcomputer having a form of a circuit module includes a central processing unit (CPU) 209, a memory module 208 (e.g., a RAM) used as a work area of the CPU 209 and having a structure illustrated in any one of FIGS. 1 to 11, a bus controller 207, an oscillator 202, a frequency divider 203, a flash memory 204, a power circuit 205, an input/output (I/O) port 206, and other peripheral circuits 201, e.g., a timer counter, which are connected via an internal bus 200.

The CPU 209 includes a command control part (not shown) and an execution part (not shown), and decodes a command fetched via the command control part and causes the execution part to perform a processing operation based on a result of decoding the fetched command. The flash memory 204 stores not only operation programs and data of the CPU 209 but also various types of data. The power circuit 205 generates high voltage for performing an erase operation and a write operation on the flash memory 204.

The frequency divider 203 divides a source frequency given from the oscillator 202 into a plurality of frequencies, and provides reference clock signals and other internal clock signals.

The internal bus 200 includes an address bus, a data bus, and a control bus.

The bus controller 207 controls bus accessing a number of cycles, in response to an access request from the CPU 209. Here, the number of cycles is related to a wait state and the width of a bus corresponding to an accessed address.

When the microcomputer is mounted on the top of a system, the CPU 209 controls the erase operation and the write operation to be performed on the flash memory 204. During a test of or manufacture of a device, performing of the erase operation and the write operation on the flash memory 204 may be directly controlled by an external memory apparatus via the I/O port 206.

According to at least one example embodiment of the inventive concept, impedances of signal lines to which different loads are applied may be controlled to be substantially the same, thereby enhancing signal integrity of a semiconductor device. Also, signal integrity may be enhanced while minimizing an increase in manufacturing costs due to an increase in the number of layers in a semiconductor device. Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A semiconductor apparatus comprising:
a first signal line commonly connected to N first semiconductor devices, wherein N is a natural number that is greater than 2; and
a second signal line commonly connected to M second semiconductor devices, wherein M is a natural number that is greater than N, wherein the first signal line has a higher impedance per unit length than the second signal line and a longer routing length than the second signal line, the longer routing length based on a different wire pattern between ends of each of the first and the second signal lines.

2. The semiconductor apparatus of claim 1, wherein
unit loads on the first semiconductor devices are substantially equal to unit loads on the second semiconductor devices, and
a load connected to the second signal line is higher than a load connected to the first signal line.

3. The semiconductor apparatus of claim 1, wherein the first semiconductor devices, the second semiconductor devices, the first signal line, and the second signal line are on the same substrate.

4. The semiconductor apparatus of claim 1, wherein the first semiconductor devices and the second semiconductor devices are embodied in respective chips.

5. The semiconductor apparatus of claim 1, wherein the impedance per unit length of the first signal line is 1.2 or more times greater than the impedance per unit length of the second signal line.

6. The semiconductor apparatus of claim 1, wherein a width of the second signal line is greater than a width of the first signal line.

7. The semiconductor apparatus of claim 6, wherein a width of the second signal line is 1.5 or more times wider than a width of the first signal line.

8. The semiconductor apparatus of claim 1, further comprising:
a third signal line commonly connected to P third semiconductor devices, wherein P is a natural number greater than M and wherein
the second semiconductor devices comprise one or more of the first semiconductor devices,
the third semiconductor devices comprise one or more of each of the first and second semiconductor devices, and
the third signal line has a lower impedance per unit length than the second impedance per unit length of the second signal line.

9. A semiconductor apparatus comprising:
a first signal line commonly connected to a plurality of semiconductor devices; and
a second signal line commonly connected to one or more of the plurality of semiconductor devices, wherein the second signal line has a higher impedance per unit length than the first signal line and has a longer routing length compared to the first signal line, the longer routing length based on a different wire pattern between ends of each of the first and the second signal lines.

10. The semiconductor apparatus of claim 9, wherein the plurality of semiconductor devices, the first signal line, and the second signal line are on a same substrate.

11. The semiconductor apparatus of claim 9, wherein the semiconductor devices are embodied in respective chips.

12. The semiconductor apparatus of claim 9, wherein the plurality of semiconductor devices comprises N first semiconductor devices, wherein N is a natural number that is greater than 2, and N second semiconductor devices, and wherein
the first signal line is commonly connected to the first semiconductor devices and the second semiconductor devices,
the second signal line is commonly connected to the first semiconductor devices; and
the third signal line is commonly connected to the second semiconductor devices, wherein the second and third signal lines have a higher impedance per unit length than the first signal line.

13. A semiconductor apparatus comprising:
a first signal line coupled to a number of first semiconductor devices; and
a second signal line coupled to a number of second semiconductor devices, wherein the number of second semiconductor devices is greater than the number of first semiconductor devices, wherein
the first signal line has a first impedance per unit length,
the second signal line has a second impedance per unit length less than the first impedance per unit length,
the first signal line extends between a first location and a second location in a first pattern,
the second signal line extends between the first location and the second location in a second pattern different from the first pattern, and
the first signal line has a longer routing length than the second signal line between the first and second locations based on a difference between the first pattern and the second pattern.

14. The semiconductor apparatus of claim 13, wherein
the first semiconductor devices are included in a first rank, and
at least a portion of the second semiconductor devices are included in a second rank.

15. The semiconductor apparatus of claim 13, further comprising:
a substrate,
wherein the first semiconductor devices are connected to a first surface of a first substrate and wherein at least a portion of the second semiconductor devices are connected to a second surface of the first substrate.

16. The semiconductor apparatus of claim 13, further comprising:
a substrate,
wherein the first and second semiconductor devices are stacked and connected to a first surface of a substrate.

17. The semiconductor apparatus of claim 13, wherein
the first signal line has a first width,
the second signal line has a second width, and
a difference between the first impedance per unit length and the second impedance per unit length is based on a difference between the first width and the second width.

18. The semiconductor apparatus of claim 13, wherein
the first signal line has a first cumulative load, and
the second signal line has a second cumulative load different from the first cumulative load.

19. The semiconductor apparatus of claim 13, wherein
the first and second signal lines have different cumulative loads, and
the first impedance per unit length allows the first signal line to have a first signal transfer rate, and
the second impedance per unit length allows the second signal line to have a second signal transfer rate which is at least substantially equal to the first signal transfer rate.

20. The semiconductor apparatus of claim 19, wherein
a first portion of the second semiconductor devices are located on a first side of the second signal line, and
a second portion of the second semiconductor devices are located on a second side of the second signal line, the second portion of the second semiconductor devices including all or a portion of the first semiconductor devices.
